(19) United States
(12) Patent Application Publication
(10) Pub. No.: US 2026/0092885 A1
(43) Pub. Date: Apr. 2, 2026

(54) MONITOR, MONITORING SYSTEM, AND DAMAGE EVALUATION SYSTEM

(71) Applicant: ABLIC Inc., Nagano (JP)

(72) Inventor: Minoru SUDO, Nagano (JP)

(73) Assignee: ABLIC Inc., Nagano (JP)

(21) Appl. No.: 19/322,586

(22) Filed: Sep. 8, 2025

(30) Foreign Application Priority Data
Sep. 30, 2024 (JP) 2024-170587

(51) Int. Cl. G01N 25/72; G01K 1/024; G01K 3/08; G01K 7/00; G01R 19/165

(52) U.S. Cl. CPC G01N 25/72; G01K 1/024; G01K 3/08; G01K 7/00; G01R 19/16576; G01K 2215/00

(57) ABSTRACT

A monitor is provided, which is capable of continuously monitoring a monitoring target in a batteryless and maintenance free manner even with a small storage capacity. The monitor is a device using, as a sensor, a thermal battery including a thermoelectric power generation element which outputs a voltage according to a temperature difference between a temperature of an atmosphere covering the monitoring target and a temperature of a contact part with the monitoring target. The monitor includes a boost circuit outputting a boost voltage obtained by boosting a voltage input from the thermal battery; an energy storage element connected to an output port of the boost circuit, and storing power supplied from the thermal battery as a sensor and boosted by the boost circuit; a voltage detection circuit outputting a control signal which includes signal levels respectively corresponding to whether or not the detected boost voltage exceeds a predetermined voltage; and a switch opening and closing a path connecting a first terminal and a second terminal connected to the output port.

### CROSS-REFERENCE TO RELATED APPLICATION

This application claims the priority benefit of Japanese application serial no. 2024-170587, filed on Sep. 30, 2024. The entirety of the above-mentioned patent application is hereby incorporated by reference herein and made a part of this specification.

### TECHNICAL FIELD

The present invention relates to a monitor, a monitoring system, and a damage evaluation system.

### RELATED ART

A monitor which monitors the temperature of a connection part of an electric wire in a batteryless manner (hereinafter, referred to as “conventional batteryless monitor”) has been proposed (for example, see Japanese Patent Application Laid-Open No. 2021-30770). The conventional batteryless monitor is configured to include a power supply part including a solar cell, an energy storage device, and a power management part (for example, see FIG. 2 of Japanese Patent Application Laid-Open No. 2021-30770). In the power supply part, the solar cell generates power by sunlight. The energy storage device is charged by the solar cell and supplies power by discharge. A power management circuit controls charging and discharging of the energy storage device.

The conventional batteryless monitor covers the power for charging the energy storage device with power generated from the solar cell. The solar cell cannot generate power in the absence of sunlight, at night, or in rainy weather. Besides, the original power generation amount of the solar cell may be impaired due to dirt on the surface of the solar cell, so maintenance such as cleaning the surface of the solar cell is required from time to time.

Due to such circumstances, the conventional batteryless monitor includes a configuration for stably operating the monitor over a long period of time. As configuration examples for stably operating the monitor in a desired period, although no longer batteryless, there are configurations such as separately providing a primary battery as an auxiliary power supply and applying a capacitor with a large capacity compared to other capacitors such as an electric double layer capacitor.

However, the configuration for stably operating the monitor in a desired period can be said to be a reducible configuration if generated power can be obtained stably. For this reason, there is room for improvement toward a batteryless monitor. Besides, the conventional batteryless monitor involves maintenance of the solar cell which is the power generation source, so there is room for improvement in maintainability. Furthermore, if the configuration for stably operating the monitor in a desired period is not required, there is also a secondary advantage in contributing to further miniaturization of the device.

The present invention provides a monitor, a monitoring system, and a damage evaluation system which are capable of continuously monitoring a monitoring target in a batteryless and maintenance free manner even with a small storage capacity.

### SUMMARY

A monitor according to at least one aspect of the present invention is attached to a monitoring target, uses a thermal battery including a thermoelectric power generation element which outputs a voltage according to a temperature difference between a temperature of an atmosphere covering the monitoring target and a temperature of a contact part in contact with the monitoring target as a sensor, and monitors the monitoring target based on the voltage according to the temperature difference. The monitor includes: a boost circuit including an input port which receives a voltage from the thermal battery, and an output port which outputs a boost voltage obtained by boosting a voltage input from the input port; an energy storage element connected to the output port of the boost circuit, and storing power supplied from the thermal battery as the sensor and boosted by the boost circuit; a voltage detection circuit detecting the boost voltage, and outputting a control signal which includes signal levels respectively corresponding to a case where the boost voltage exceeds a predetermined voltage and a case where the boost voltage does not exceed the predetermined voltage from an output port; and a switch including a first terminal connected to the output port of the boost circuit and a second terminal, and opening and closing a path connecting the first terminal and the second terminal based on the control signal.

A monitoring system according to at least one aspect of the present invention transmits a monitoring signal which includes identification information of a thermal battery from a monitor to a receiver receiving the monitoring signal. The monitor is attached to a monitoring target, uses the thermal battery including a thermoelectric power generation element which outputs a voltage according to a temperature difference between a temperature of an atmosphere covering the monitoring target and a temperature of a contact part with the monitoring target as a sensor, and monitors the monitoring target based on the voltage according to the temperature difference. The monitoring system includes the monitor which includes a boost circuit including an input port which receives a voltage from the thermal battery, and an output port which outputs a boost voltage obtained by boosting a voltage input from the input port; an energy storage element connected to the output port of the boost circuit, and storing power supplied from the thermal battery as the sensor and boosted by the boost circuit; a voltage detection circuit detecting the boost voltage, and outputting a control signal which includes signal levels respectively corresponding to a case where the boost voltage exceeds a predetermined voltage and a case where the boost voltage does not exceed the predetermined voltage from an output port; and a transmitter circuit connected to the output port of the boost circuit and an input port of the voltage detection circuit via a switch which is controlled to open and close based on the control signal.

A damage evaluation system according to at least one aspect of the present invention transmits a monitoring signal which includes identification information of a thermal battery from a monitor to an evaluator evaluating a damage condition of a monitoring target. The monitor is attached to the monitoring target, uses the thermal battery including a thermoelectric power generation element which outputs a voltage according to a temperature difference between a temperature of an atmosphere covering the monitoring target and a temperature of a contact part with the monitoring target as a sensor, and monitors the monitoring target based on the voltage according to the temperature difference. The damage evaluation system includes: the monitor which includes a boost circuit including an input port which receives a voltage from the thermal battery, and an output port which outputs a boost voltage obtained by boosting a voltage input from the input port; an energy storage element connected to the output port of the boost circuit, and storing power supplied from the thermal battery as the sensor and boosted by the boost circuit; a voltage detection circuit detecting the boost voltage, and outputting a control signal which includes signal levels respectively corresponding to a case where the boost voltage exceeds a predetermined voltage and a case where the boost voltage does not exceed the predetermined voltage from an output port; and a transmitter circuit connected to the voltage detection circuit via a switch which is controlled to open and close based on the control signal, and transmitting to the evaluator evaluating the damage condition of the monitoring target based on the monitoring signal including the identification information of the thermal battery.

According to the present invention, the monitoring target can be continuously monitored in a batteryless and maintenance free manner even with a small storage capacity.

### BRIEF DESCRIPTION OF THE DRAWINGS

FIG. 1 is a schematic diagram illustrating a configuration example of a monitor and a monitoring system according to an embodiment of the present invention.

FIG. 2 is a schematic diagram illustrating a configuration example of a thermal battery which is a sensor of the monitor according to the present embodiment.

FIG. 3 is an explanatory diagram illustrating power generation characteristics (power generation output with respect to temperature difference) of a thermoelectric power generation element included in the thermal battery.

FIG. 4 is an explanatory diagram illustrating boost characteristics (boost time with respect to generation voltage) of a boost circuit included in the monitor according to the present embodiment.

FIG. 5 is a schematic diagram illustrating a configuration example of a damage evaluation system according to the present embodiment.

FIG. 6 is a schematic diagram illustrating an application example of the damage evaluation system according to the present embodiment.

### DESCRIPTION OF THE EMBODIMENTS

Hereinafter, a monitor, a monitoring system, and a damage evaluation system according to embodiments of the present invention will be described with reference to the drawings.

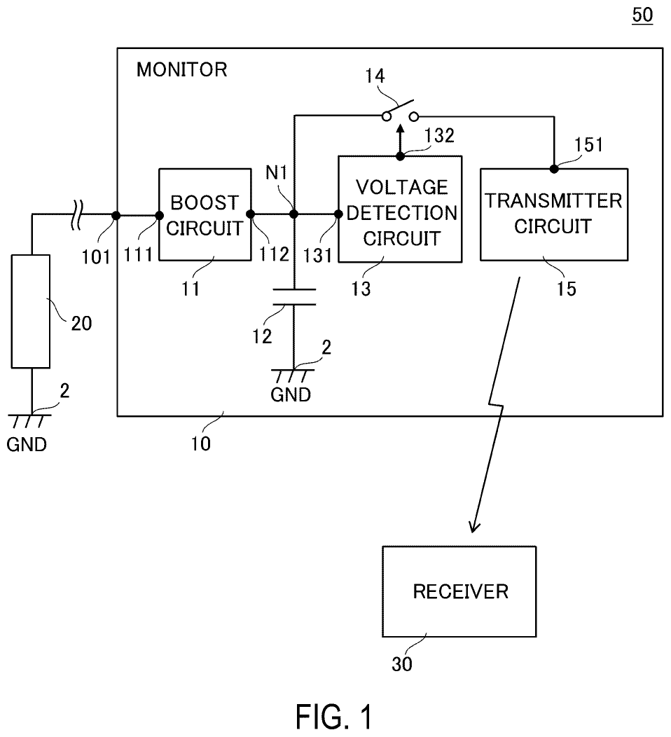

FIG. 1 is a schematic diagram illustrating a configuration example of a monitor 10 and a monitoring system 50, which are one example of the monitor and the monitoring system, according to the present embodiment.

The monitoring system 50 includes at least one monitor 10 and a receiver 30 communicably connected to the monitor 10.

The monitor 10 includes a boost circuit 11, an energy storage element 12, a voltage detection circuit 13, a switch 14, and a transmitter circuit 15, and is configured to be connectable to a thermal battery 20. Here, a connection point between the thermal battery 20 and the monitor 10 is referred to as an input node 101.

The boost circuit 11 includes an input port 111 which is the same node as the input node 101, and an output port 112. The energy storage element 12 includes a first terminal connected to the output port 112, and a second terminal connected to a GND terminal 2 which is a node supplying a ground voltage GND, as one example of a power supply voltage.

The voltage detection circuit 13 includes an input port 131 connected to a node N1 which is a connection point between the output port 112 and the first terminal of the energy storage element 12, and an output port 132 outputting a control signal which includes a signal level corresponding to whether or not a boost voltage supplied to the input port 131 exceeds a predetermined voltage.

The switch 14 includes a first terminal connected to the output port 112, a second terminal, and a control terminal connected to the output port 132, and is subjected to switching control (opening and closing control) between an open state (opened state) and a short-circuit state (closed state) for the first terminal and the second terminal according to the signal level of the control signal. In the following description, the first terminal and the second terminal of the switch 14 are simply referred to as both terminals.

The transmitter circuit 15 is a circuit capable of communicating a monitoring signal to the outside of the monitor 10, such as the receiver 30. The transmitter circuit 15 includes an input port 151 connected to the second terminal of the switch 14. For example, the transmitter circuit 15 capable of wireless transmission wirelessly transmits the monitoring signal to the receiver 30 outside the monitor 10.

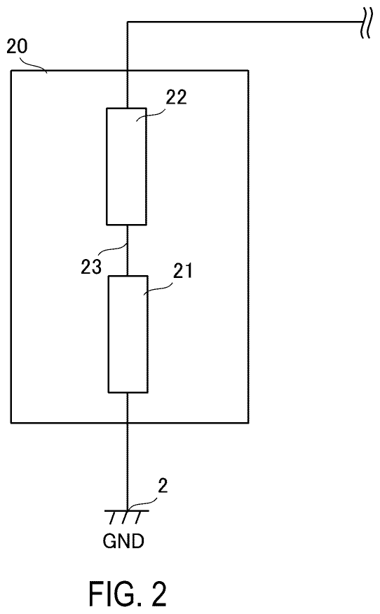

FIG. 2 is a schematic diagram illustrating a configuration example of the thermal battery 20.

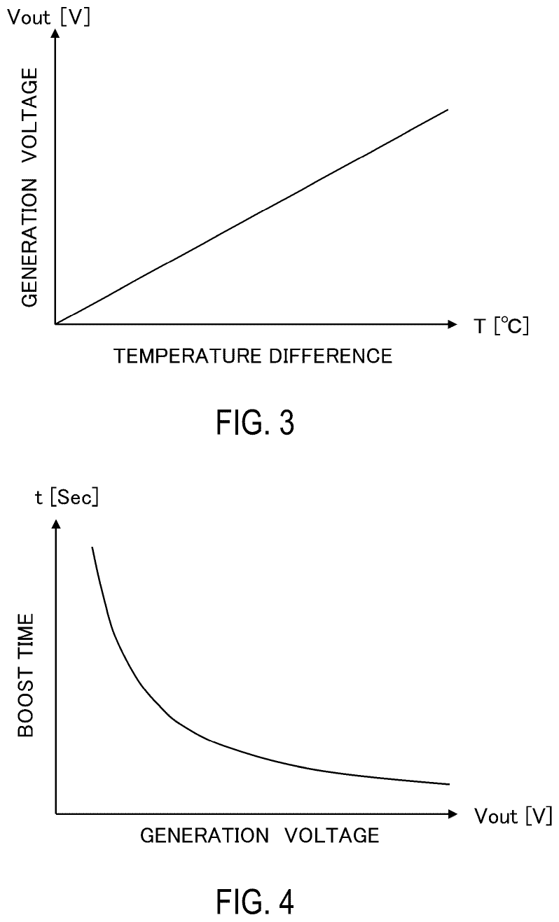

FIG. 3 is an explanatory diagram exemplifying the power generation characteristics (power generation output with respect to temperature difference) of thermoelectric power generation elements 21 and 22 included in the thermal battery 20, with the horizontal axis representing temperature difference T [° C.] and the vertical axis representing generation voltage Vout [V].

The thermal battery 20 as a sensor connected to the monitor 10 is configured to include at least one thermoelectric power generation element, for example, two thermoelectric power generation elements (21 and 22). The thermoelectric power generation elements 21 and 22 are elements which connect a p-type semiconductor element and an n-type semiconductor element in series and generate a voltage proportional to the temperature difference between a high temperature side surface and a low temperature side surface (see FIG. 3).

The thermal battery 20 exemplified in FIG. 2 includes two thermoelectric power generation elements 21 and 22 connected in series by a connection conductor 23. The connection conductor 23 can be any object which can electrically connect the thermoelectric power generation element 21 and the thermoelectric power generation element 22, that is, any conductor. However, in the case of emphasizing the degree of freedom during attachment of the thermoelectric power generation element 21 and the thermoelectric power generation element 22, that is, ease of attachment, it is preferable to use a conductor having appropriate flexibility and length.

Next, the operations and effects of the monitor 10 and the monitoring system 50 will be described.

The thermoelectric power generation elements 21 and 22 constituting the thermal battery 20 generate power in proportion to the temperature difference between the surface attached to a monitoring target (hereinafter, referred to as “attached surface”) and the surface not attached, that is, the surface exposed to the atmosphere covering the thermoelectric power generation elements 21 and 22 (hereinafter, referred to as “exposed surface”). Assuming that the high temperature side is 50 [° C.] and the low temperature side is 30 [° C.], the temperature difference is 20 [° C.], so in the case of one thermoelectric power generation element 21 (or 22) having a power generation capability of 10 [mV/° C.], power of 200 [mV] is generated.

The power generated by the thermal battery 20 is supplied to the connected monitor 10 (more specifically, the boost circuit 11). The generation voltage of the thermal battery 20 becomes a low voltage of 100 [mV/unit] order or less in the case of the power generation capability being the example described above, for example, according to a small temperature difference such as less than 10 [° C.], so the generation voltage cannot directly drive the transmitter circuit 15. The boost circuit 11 boosts the voltage supplied from the input port 111 to a voltage (for example, 2.0 [V]) which enables the transmitter circuit 15 to perform a desired operation. The energy supplied with power from the thermal battery 20 and boosted by the boost circuit 11 is stored in the energy storage element 12.

FIG. 4 is an explanatory diagram exemplifying the boost characteristics (boost time with respect to generation voltage) of the boost circuit 11, with the horizontal axis representing the generation voltage Vout [V] of the thermal battery 20 and the vertical axis representing boost time t [seconds].

The boost time t [seconds] of the boost circuit 11 depends on the voltage supplied to the boost circuit 11, that is, the generation voltage Vout [V] of the thermal battery 20. As illustrated in FIG. 4, the boost time t [seconds] becomes longer according to a low generation voltage Vout [V], and becomes shorter according to a high generation voltage Vout [V].

The voltage detection circuit 13 detects whether or not the voltage at the output port 112 of the boost circuit 11, the first terminal of the energy storage element 12, and the input port 131 of the voltage detection circuit 13, that is, the node N1, exceeds a predetermined voltage set as a threshold voltage, and outputs a control signal including a signal level corresponding to the detection result from the output port 132. The threshold voltage of the voltage detection circuit 13 is set to a voltage equal to or higher than a voltage which can supply energy enabling the transmitter circuit 15 to transmit the monitoring signal once, as the charge amount of the energy storage element 12.

The voltage detection circuit 13 outputs a control signal of a first signal level, such as a low level, from the output port 132 in the case of the voltage at the node N1 being equal to or lower than the threshold voltage of the voltage detection circuit 13. On the other hand, in response to the boost of the supplied generated power being started and the voltage at the node N1 rising and eventually exceeding the threshold voltage of the voltage detection circuit 13, the voltage detection circuit 13 outputs a control signal of a second signal level, such as a high level, from the output port 132.

The switch 14, for example, opens a path connecting both terminals of the switch 14 in response to receiving a control signal of the first signal level at the control terminal, and closes the path connecting both terminals in response to receiving a control signal of the second signal level at the control terminal. The switch 14 is in an opened state with both terminals opened until the voltage at the node N1 exceeds the threshold voltage of the voltage detection circuit 13, that is, in the case of receiving a control signal of the first signal level at the control terminal. In the case of the voltage at the node N1 exceeding the threshold voltage of the voltage detection circuit 13, that is, in the case of receiving a control signal of the second signal level at the control terminal, the switch 14 becomes in a closed state with both terminals short-circuited.

Thus, in response to the voltage at the node N1 rising and exceeding the threshold voltage of the voltage detection circuit 13, the switch 14 transitions from the opened state to the closed state, and the input port 151 of the transmitter circuit 15 is short-circuited with the node N1. The transmitter circuit 15 short-circuited with the node N1 transmits the monitoring signal to the receiver 30 because a voltage which enables transmission of the monitoring signal to the receiver 30 outside is supplied to the input port 151. The monitoring signal includes identification information which enables identification of the thermal battery 20 connected to the monitor 10.

Here, the voltage which enables the transmitter circuit 15 to transmit the monitoring signal once will be described. In the case of the transmitter circuit 15 being configured as a wireless transmitter circuit capable of wireless communication, the wireless communication method to be adopted is arbitrary as long as wireless communication between the monitor 10 and the receiver 30 is possible. However, since the voltage and energy which enable transmission of the monitoring signal once differ according to the wireless communication method to be adopted, the capacity value of the energy storage element 12 and the boost voltage of the boost circuit 11 are determined according to the wireless communication method to be adopted.

For example, upon comparison between the case of adopting Bluetooth (registered trademark) Low Energy (hereinafter, referred to as “BLE”) which is suitable for short communication distance, and the case of adopting LoRa WAN (registered trademark) which is suitable for longer communication distance than BLE, the transmitter circuit 15 adopting LoRa WAN (registered trademark) requires approximately 10 times the wireless communication energy compared to the transmitter circuit 15 adopting BLE. Thus, the capacity value of the energy storage element 12 of the monitor 10 including the transmitter circuit 15 adopting LoRa WAN (registered trademark) is configured to be approximately 10 times the capacity value of the energy storage element 12 of the monitor 10 including the transmitter circuit 15 adopting BLE.

The receiver 30 receives the monitoring signal from the monitor 10. Since the monitoring signal received by the receiver 30 includes identification information which enables identification of the thermal battery 20 connected to the monitor 10, even in the monitoring system 50 including n (which is natural number) monitors 10, the receiver 30 can individually grasp the states of n (natural number) monitoring targets.

As described above, by including the boost circuit 11, the monitor 10 and the monitoring system 50 can be configured to be capable of transmitting the monitoring signal to the outside such as the receiver 30, even with small supplied generated power, in the case of the boost circuit 11 obtaining a boost voltage which exceeds a voltage enabling transmission of the monitoring signal once with respect to the generated power obtained at the time of assumed abnormality occurrence.

According to the monitor 10 and the monitoring system 50, by adopting the thermal battery 20 which can serve both as a power generation source and a sensor, a device and a system which are not affected by weather and time can be configured compared to the conventional monitor and monitoring system which adopt solar cells as the power generation source. In addition, since maintenance such as surface cleaning for solar cells is not required, the burden of inspection and maintenance of the power generation source can be reduced compared to the conventional monitor and monitoring system which adopt solar cells as the power generation source.

Further, in the case of the monitor 10 including the energy storage element 12 including one terminal connected to the output port 112 of the boost circuit 11, energy is stored in the energy storage element 12 as long as power supply continues even intermittently. Thus, the minimum capacity value of the energy storage element 12 can be reduced to a capacity value capable of storing power which enables the transmitter circuit 15 to transmit the monitoring signal once. Accordingly, unlike the conventional monitor and monitoring system which adopt solar cells, it is not required to separately provide a primary battery as an auxiliary power supply or to include an energy storage element with a large capacity such as an electric double layer capacitor. Thus, the monitor 10 smaller than the conventional monitor can be provided.

In the monitor 10 and the monitoring system 50, in the case of the thermal battery 20 being configured with the thermoelectric power generation elements 21 and 22 connected in series, the generation voltage can be made higher compared to the case of one thermoelectric power generation element, and the boost time, that is, the time interval of monitoring signal transmission, can be shortened. Further, in the case of including the thermoelectric power generation elements 21 and 22, the monitoring operation can continue as long as power is generated by one of the thermoelectric power generation elements 21 and 22, so the monitor 10 can be configured to be resistant to sensor failure.

In addition, according to the monitor 10 and the monitoring system 50, event-driven type device and system which perform wireless transmission in the case of having an abnormality (temperature rise due to heat generation) in the monitoring target can be configured. Furthermore, the monitor 10 and the monitoring system 50 can continue monitoring the monitoring target while receiving power supply even in a batteryless manner, because the thermal battery 20 serves both as a power generation source and a sensor. In the monitor 10 and the monitoring system 50, the larger the temperature difference becomes, the shorter the time interval for transmitting the monitoring signal becomes, and the smaller the temperature difference becomes, the longer the time interval for transmitting the monitoring signal becomes.

Accordingly, in the monitor 10 and the monitoring system 50, as long as the transmission time interval of the monitoring signal from the transmitter circuit 15, that is, the time interval for receiving the monitoring signal at the receiver 30, is monitored, it is not required to constantly monitor temperature from wireless transmission data as in the conventional monitor and monitoring system. Thus, power consumption required for the operations of the monitor 10 and the monitoring system 50 can be suppressed, which contributes to making the monitor 10 and the monitoring system 50 batteryless.

In addition, adopting the thermal battery 20 which obtains power generation output based on the temperature difference between the high temperature side and the low temperature side as a sensor is superior in terms of the capability to consider changes in the temperature of the atmosphere surrounding the monitoring target, compared to the case of adopting a temperature sensor which simply measures the temperature of the contact part as a sensor. For example, since changes in air temperature which vary with seasonal transitions can be taken into consideration, abnormalities in the monitoring target can be detected more accurately.

In this way, as long as it is possible to store energy which enables transmission of the monitoring signal once, the monitor 10 and the monitoring system 50 can continuously monitor the monitoring target in a batteryless and maintenance free manner even with the energy storage element 12 having a small capacity value.

Next, a case where the monitoring system according to the present embodiment functions as a damage evaluation system for evaluating the damage condition of the monitoring target will be described.

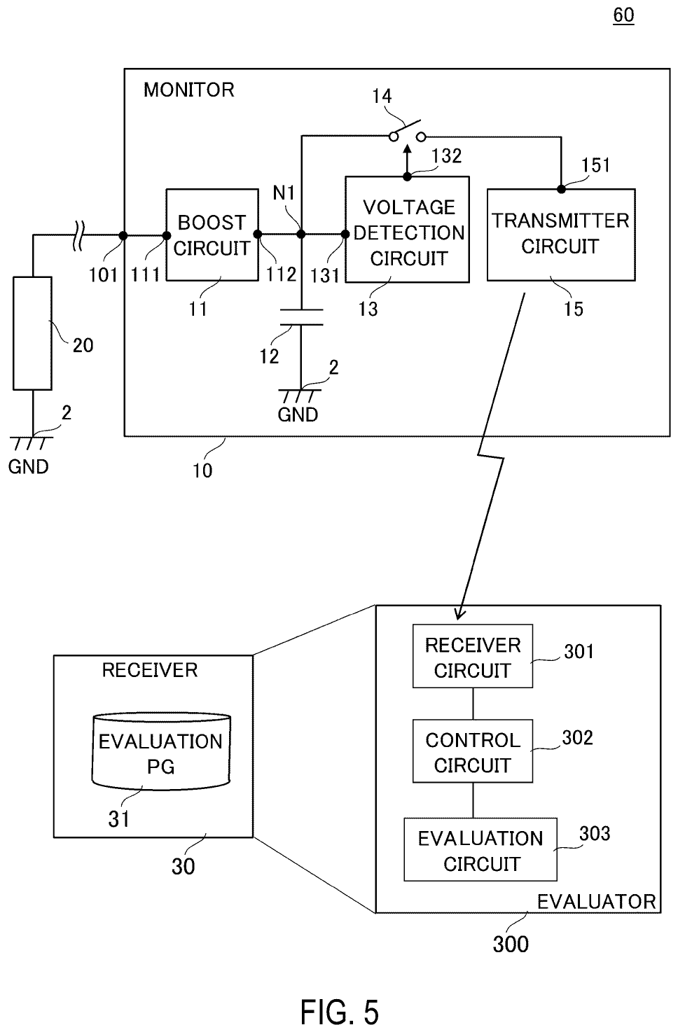

FIG. 5 is a schematic diagram illustrating the configuration of a damage evaluation system 60 which is one example of the damage evaluation system according to the present embodiment.

The damage evaluation system 60 is one aspect of the monitoring system 50, and is an aspect in which the receiver 30 of the monitoring system 50 functions as an evaluator 300. That is, the damage evaluation system 60 is configured to include the monitor 10 and the evaluator 300 having a function of receiving the monitoring signal and a function of evaluating the damage condition of the monitoring target.

The evaluator 300 is realized, for example, by causing hardware such as a computer capable of executing a program (hereinafter, referred to as “PG”) to execute an evaluation PG 31 which is software. In the case of the receiver 30 having a processor capable of executing PG, the processor executes the evaluation PG 31, thereby realizing in the receiver 30 which is hardware, a function of receiving the monitoring signal and a function of evaluating the damage condition of the monitoring target. That is, the evaluation PG 31 and the receiver 30 cooperate to cause the receiver 30 to function as the evaluator 300 which includes a receiver circuit 301 which is means for receiving the monitoring signal, an evaluation circuit 303 which is means for evaluating the damage condition of the monitoring target, and a control circuit 302 which controls the receiver circuit 301 and the evaluation circuit 303.

The control circuit 302 provides the monitoring signal received by the receiver circuit 301 to the evaluation circuit 303 which evaluates the damage condition of the monitoring target.

The evaluation circuit 303 includes reception history information of the received monitoring signal and information representing a relationship between a time interval for receiving the monitoring signal and a damage degree corresponding to a resistance value of the monitoring target. The evaluation circuit 303 evaluates the damage condition of the monitoring target, to which the thermoelectric power generation elements 21 and 22 which are sensors are attached, based on a reception interval of the monitoring signal received from the receiver circuit 301.

The time interval for receiving the monitoring signal corresponds to the time until the voltage at the node N1 exceeds the threshold voltage of the voltage detection circuit 13, that is, the boost time by the boost circuit 11. Thus, the larger the generated power supplied from the thermal battery 20, the shorter the time interval for receiving the monitoring signal becomes, and the smaller the generated power supplied from the thermal battery 20, the longer the time interval for receiving the monitoring signal becomes.

Also, there is a relationship between conductor damage and resistance value, in which the resistance value is small in the case of small damage, and the resistance value is also large in case of large damage. From this, it can be evaluated that the larger the joule heat generated during conduction, that is, the higher the temperature of the contact part with the monitoring target, the larger the damage of the conductor. The evaluation circuit 303 evaluates that the damage of the monitoring target is small in the case of a small temperature difference corresponding to the voltage of the thermoelectric power generation elements 21 and 22 attached to the monitoring target in consideration of the above-described relationship, and evaluates that the damage of the monitoring target is large in the case of a large temperature difference corresponding to the voltage of the thermoelectric power generation elements 21 and 22.

Here, the information representing the relationship between the time interval for receiving the monitoring signal and the damage degree of the monitoring target can be obtained based on information representing the relationship between the time interval for receiving the monitoring signal and the voltage according to the temperature difference of the thermoelectric power generation elements 21 and 22, and information representing the relationship between the voltage according to the temperature difference of the thermoelectric power generation elements 21 and 22 attached to the monitoring target and the damage degree of the monitoring target. Further, the information representing the relationship between the time interval for receiving the monitoring signal and the damage degree of the monitoring target can be of any format as long as the damage degree of the monitoring target, which is the final result, can be obtained.

In terms of describing the evaluator 300 from the aspect of procedure, the procedure for the evaluator 300 to evaluate the damage condition of the monitoring target (hereinafter, referred to as “damage evaluation procedure”) includes a step of receiving the monitoring signal from the monitor 10, and a step of obtaining the time interval for receiving the monitoring signal and evaluating the damage condition of the monitoring target based on information representing the relationship between the time interval for receiving the monitoring signal and the damage degree of the monitoring target. In other words, the above-described evaluation PG 31 is a PG which causes hardware capable of executing a program to execute the damage evaluation procedure.

Next, an application example of the damage evaluation system 60 will be described.

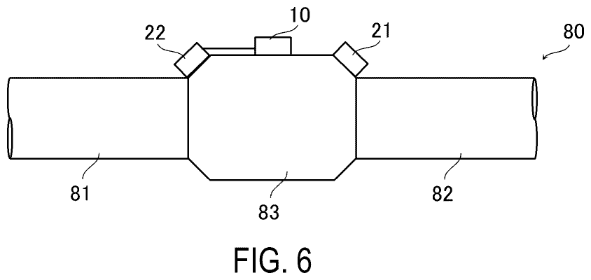

FIG. 6 is a schematic diagram illustrating a state where the monitor 10 and the thermoelectric power generation elements 21 and 22 serving as sensors are attached to an electric wire 80 which is the monitoring target for damage evaluation, as an application example of the damage evaluation system 60.

According to FIG. 6, the electric wire 80 is configured by inserting two electric wires 81 and 82, which are one example of multiple electric wires, into a sleeve 83 which is a metal connection tube, compressing in this state, and mechanically and electrically connecting (crimping) the electric wires 81 and 82. In the electric wire 80 in which the electric wires 81 and 82 are crimped and mechanically and electrically connected into one wire, breakage is more likely to occur at the sleeve 83, which is the connection part, compared to other parts. Thus, by attaching the thermoelectric power generation elements 21 and 22 serving as sensors to the sleeve 83, which is the connection part, respectively at different positions (a first position and a second position), the temperature of the connection part can be estimated, making it possible to evaluate the damage degree of the electric wire 80 based on the estimated temperature.

In the monitoring target exemplified in FIG. 6, a current flows through the electric wire 80, so in the case of damage of the sleeve 83 progressing for some reason, the resistance value thereof increases and the generated joule heat increases. Since the increase in joule heat raises the temperature of the sleeve 83, the temperature on the high temperature side in the thermoelectric power generation elements 21 and 22, which is the surface attached to the sleeve 83, rises. The rise of the temperature on the high temperature side causes the temperature difference with the exposed surface on the low temperature side to expand, so the generation voltage increases.

According to the damage evaluation system 60 including the thermoelectric power generation elements 21 and 22 attached to the sleeve 83, the temperature of the sleeve 83, which is the connection part of the electric wire 80, can be continuously monitored, so changes in joule heat generated in the sleeve 83, that is, changes in resistance of the connection part, can be detected at an early stage. Thus, even in the case of an abnormality in which the temperature is higher than normal occurring at the connection part of the electric wire 80 which is the monitoring target, the abnormality can be detected early, and the location where the abnormality is detected can be maintained efficiently.

As described above, according to the monitor 10 and the damage evaluation system 60, in addition to the effects of the monitor 10 and the monitoring system 50 described above, an increase in resistance value accompanying damage progression can be captured as a temperature rise in the case of the monitoring target being a current-carrying conductor such as the electric wire 80. Thus, the damage condition of the monitoring target can be evaluated based on information representing the relationship between the time interval for receiving the monitoring signal and the damage degree of the monitoring target. That is, according to the monitor 10 and the damage evaluation system 60, monitoring of the monitoring target and evaluation of the damage condition of the monitoring target can be continued in a batteryless and maintenance free manner even in the case of the energy storage element 12 having a small capacity value.

Nevertheless, the present invention is not limited to the embodiments as described above, and in the implementation stage, it is possible to implement the present invention in various forms other than the examples described above. Various omissions, additions, replacements, or changes can be made within a range which does not depart from the gist of the present invention.

For example, although the monitor 10 is described as including the transmitter circuit 15, the monitor 10 may be configured to omit the transmitter circuit 15 and output the monitoring signal with the input port 151 of the transmitter circuit 15 as an output node of the monitor 10. The thermal battery 20 may include at least one thermoelectric power generation element 21 (or 22), and does not necessarily include two. That is, the monitor 10 is applicable even in the case of two or more monitoring points.

Although the example describes a case where the evaluator 300 is the same device as the receiver 30 in the damage evaluation system 60 described above, the evaluator 300 may be configured as a separate device from the receiver 30.

The voltage detection circuit 13 may have a hysteresis function. In addition, the monitor 10 may further have a function of keeping the switch 14 in the closed state for a certain time (until communication is completed) after the voltage detection circuit 13 detects that the voltage at the node N1 exceeds the threshold voltage of the voltage detection circuit 13. The function of keeping the switch 14 in the closed state for a certain time may be provided in the voltage detection circuit 13, or may be provided by adding a circuit having the function.

These embodiments and modifications thereof are included in the scope and gist of the invention, and are included in the invention described in the claims and the equivalent scope thereof.

What is claimed is:

1. A monitor, attached to a monitoring target, using a thermal battery including a thermoelectric power generation element which outputs a voltage according to a temperature difference between a temperature of an atmosphere covering the monitoring target and a temperature of a contact part in contact with the monitoring target as a sensor, and monitoring the monitoring target based on the voltage according to the temperature difference, the monitor comprising:
a boost circuit including an input port which receives a voltage from the thermal battery, and an output port which outputs a boost voltage obtained by boosting a voltage input from the input port;
an energy storage element connected to the output port of the boost circuit, and storing power supplied from the thermal battery as the sensor and boosted by the boost circuit;
a voltage detection circuit detecting the boost voltage, and outputting a control signal which has signal levels respectively corresponding to a case where the boost voltage exceeds a predetermined voltage and a case where the boost voltage does not exceed the predetermined voltage from an output port; and
a switch including a first terminal connected to the output port of the boost circuit and a second terminal, and opening and closing a path connecting the first terminal and the second terminal based on the control signal.

2. The monitor according to claim 1, comprising a transmitter circuit which includes an input port connected to the second terminal of the switch, and transmits a monitoring signal comprising identification information of the thermal battery in response to receiving a voltage of the same node as the output port of the boost circuit via the switch,
wherein the predetermined voltage is set to be equal to or higher than a minimum voltage which enables the transmitter circuit to transmit the monitoring signal.

3. The monitor according to claim 2, wherein the transmitter circuit is configured to be capable of wirelessly transmitting the monitoring signal having the identification information of the thermal battery.

4. The monitor according to claim 2, wherein the energy storage element has a capacity value capable of storing power which enables the transmitter circuit to transmit the monitoring signal once.

5. A monitoring system, transmitting a monitoring signal which has identification information of a thermal battery from a monitor to a receiver receiving the monitoring signal, the monitor being attached to a monitoring target, using the thermal battery including a thermoelectric power generation element which outputs a voltage according to a temperature difference between a temperature of an atmosphere covering the monitoring target and a temperature of a contact part with the monitoring target as a sensor, and monitoring the monitoring target based on the voltage according to the temperature difference, the monitoring system comprising:
the monitor which comprises a boost circuit including an input port which receives a voltage from the thermal battery, and an output port which outputs a boost voltage obtained by boosting a voltage input from the input port; an energy storage element connected to the output port of the boost circuit, and storing power supplied from the thermal battery as the sensor and boosted by the boost circuit; a voltage detection circuit detecting the boost voltage, and outputting a control signal which has signal levels respectively corresponding to a case where the boost voltage exceeds a predetermined voltage and a case where the boost voltage does not exceed the predetermined voltage from an output port; and a transmitter circuit connected to the output port of the boost circuit and an input port of the voltage detection circuit via a switch which is controlled to open and close based on the control signal.

6. A damage evaluation system, transmitting a monitoring signal which has identification information of a thermal battery from a monitor to an evaluator evaluating a damage condition of a monitoring target, the monitor being attached to the monitoring target, using the thermal battery including a thermoelectric power generation element which outputs a voltage according to a temperature difference between a temperature of an atmosphere covering the monitoring target and a temperature of a contact part with the monitoring target as a sensor, and monitoring the monitoring target based on the voltage according to the temperature difference, the damage evaluation system comprising:
the monitor which comprises a boost circuit including an input port which receives a voltage from the thermal battery, and an output port which outputs a boost voltage obtained by boosting a voltage input from the input port; an energy storage element connected to the output port of the boost circuit, and storing power supplied from the thermal battery as the sensor and boosted by the boost circuit; a voltage detection circuit detecting the boost voltage, and outputting a control signal which has signal levels respectively corresponding to a case where the boost voltage exceeds a predetermined voltage and a case where the boost voltage does not exceed the predetermined voltage from an output port; and a transmitter circuit connected to the voltage detection circuit via a switch which is controlled to open and close based on the control signal, and transmitting to the evaluator evaluating the damage condition of the monitoring target based on the monitoring signal having the identification information of the thermal battery.

7. The damage evaluation system according to claim 6, comprising the evaluator, wherein the evaluator includes:
a receiver circuit receiving the monitoring signal transmitted from the transmitter circuit;
an evaluation circuit estimating the voltage according to the temperature difference based on a relationship between a time interval at which the receiver circuit receives the monitoring signal and the voltage according to the temperature difference, and evaluating the damage condition of the monitoring target; and
a control circuit controlling the receiver circuit and the evaluation circuit.

8. The damage evaluation system according to claim 6, wherein the thermal battery includes:
a first thermoelectric power generation element attached at a first position of the monitoring target; and
a second thermoelectric power generation element attached at a second position which is a different position from the first position and is in contact with the monitoring target, and connected in series with the first thermoelectric power generation element.

9. The damage evaluation system according to claim 7, wherein the thermal battery includes:
a first thermoelectric power generation element attached at a first position of the monitoring target; and
a second thermoelectric power generation element attached at a second position which is a different position from the first position and is in contact with the monitoring target, and connected in series with the first thermoelectric power generation element.
